(19) United States
(12) Patent Application Publication
(10) Pub. No.: US 2025/0330137 A1
(43) Pub. Date: Oct. 23, 2025

(54) FILTER DEVICE

(71) Applicant: Murata Manufacturing Co., Ltd., Nagaokakyo-shi (JP)

(72) Inventor: Keisuke OGAWA, Nagaokakyo-shi (JP)

(21) Appl. No.: 19/046,732

(22) Filed: Feb. 6, 2025

(30) Foreign Application Priority Data
Apr. 23, 2024 (JP) 2024-069893

(51) Int. Cl. H03H 7/12; H03H 1/00

(52) U.S. Cl. CPC H03H 7/12; H03H 1/00; H03H 2001/0085

(57) ABSTRACT

A filter device includes a multilayer body, an input terminal, an output terminal, a first filter including first resonators, and a second filter including second resonators. In the first filter, a signal from the input terminal is transmitted to the second filter through the first resonators. In the second filter, the signal from the first filter is transmitted to the output terminal through the second resonators. Jump coupling is formed between one of the first resonators and one of the second resonators. One main coupling of the coupling between a first pair of the first and second resonators and the coupling between a second pair of the first and second resonators is magnetic coupling, and the other main coupling is electric field coupling.

### CROSS REFERENCE TO RELATED APPLICATIONS

This application claims the benefit of priority to Japanese Patent Application No. 2024-069893 filed on Apr. 23, 2024. The entire contents of this application are hereby incorporated herein by reference.

### BACKGROUND OF THE INVENTION

### 1. Field of the Invention

The present disclosure relates to filter devices, and more particularly to techniques for improving the attenuation characteristics of a non-pass band in band pass filters.

### 2. Description of the Related Art

Japanese Patent No. 7111214 and Japanese Unexamined Patent Application Publication No. 2020-198482 disclose a band pass filter having a multistage configuration of a plurality of LC parallel resonators between an input terminal and an output terminal. In these documents, a sub-path including jump coupling that bypasses some of the resonators is formed in addition to a main path in which a signal is transmitted sequentially through the plurality of resonators from the input terminal to the output terminal. By forming such a sub-path including jump coupling, an attenuation pole is added in a non-pass band, making it possible to improve attenuation characteristics in the non-pass band compared to the case where there is no sub-path.

### SUMMARY OF THE INVENTION

In the configuration of Japanese Patent No. 7111214, jump coupling is formed in a portion of the first resonator closest to the input terminal and the last resonator closest to the output terminal, and the resonators in the middle are disposed sequentially in a direction from the input terminal to the output terminal. In such a configuration, the larger the number of the resonators, the narrower the interval between the resonators. This may limit the adjustment range of the coupling degree for the resonators in the middle and the degree of freedom in designing the jump coupling.

In the case of Japanese Unexamined Patent Application Publication No. 2020-198482, on the other hand, resonators are arranged so that the direction of a main signal transmission path is reversed in the middle. Therefore, compared to the configuration of Japanese Patent No. 7111214, the degree of freedom in designing the jump coupling in the middle is relaxed. However, since the input terminal and the output terminal are disposed adjacent to each other, the isolation between the input and output terminals can be easily decreased, leading to deterioration in attenuation characteristics.

Example embodiments of the present invention improve the attenuation characteristics of a non-pass band in filter devices each including a plurality of resonators.

A filter device according to an example embodiment of the present disclosure includes a dielectric substrate including a first main surface and a second main surface, an input terminal and an output terminal on the second main surface, a first filter, and a second filter. The first filter includes a first resonator, a second resonator, a third resonator, and a fourth resonator in the dielectric substrate. The second filter includes a fifth resonator, a sixth resonator, a seventh resonator, and an eighth resonator in the dielectric substrate. In the first filter, a signal transmitted from the input terminal is transmitted to the second filter through the first resonator, the second resonator, the third resonator, and the fourth resonator in this order. In the second filter, the signal transmitted from the first filter is transmitted to the output terminal through the fifth resonator, the sixth resonator, the seventh resonator, and the eighth resonator in this order. Jump coupling is present between the third resonator and the sixth resonator. One main coupling of coupling between the fourth resonator and the fifth resonator and coupling between the third resonator and the sixth resonator is magnetic coupling, and the other main coupling is electric field coupling.

A filter device according to another example embodiment of the present disclosure includes an input terminal, an output terminal, first to fourth inductor circuits, first to third capacitor circuits, a first capacitor, and a second capacitor. The first capacitor is connected between the input terminal and a ground potential. The second capacitor is connected between the output terminal and the ground potential. The first inductor circuit is connected between the input terminal and the first capacitor circuit. The second inductor circuit is connected between the first capacitor circuit and the second capacitor circuit. The second inductor circuit is connected between the second capacitor circuit and the third capacitor circuit. The fourth inductor circuit is connected between the third capacitor circuit and the output terminal. The first inductor circuit and the second inductor circuit are magnetically coupled, the second inductor circuit and the third inductor circuit are magnetically coupled, and the third inductor circuit and the fourth inductor circuit are magnetically coupled.

The filter devices according to example embodiments of the present disclosure improve the attenuation characteristics of a non-pass band in the filter device each including a plurality of resonators.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a block diagram of a communication device having a high-frequency front-end circuit to which a filter device according to Example Embodiment 1 of the present invention is applied.

FIG. 2 is a diagram for explaining a topology of the filter device according to Example Embodiment 1 of the present invention.

FIG. 3 is an equivalent circuit diagram of the filter device according to Example Embodiment 1 of the present invention.

FIG. 4 is an external perspective view of the filter device according to Example Embodiment 1 of the present invention.

FIG. 5 is an exploded perspective view showing an example of a multilayer structure of the filter device in FIG. 4.

FIG. 6 is a top view of the filter device in FIG. 4.

FIG. 7 is a diagram for explaining a topology of a filter device according to a comparative example.

FIGS. 8A and 8B are diagrams for explaining filter characteristics of the filter devices according to Example Embodiment 1 of the present invention and the comparative example.

FIG. 9 is a diagram showing a configuration example for adjusting magnetic coupling between resonators.

FIG. 10 is a diagram showing a first example of adjusting the magnetic coupling between the resonators using ground vias.

FIG. 11 is a diagram showing a second example of adjusting the magnetic coupling between the resonators using the ground vias.

FIG. 12 is a diagram showing a third example of adjusting the magnetic coupling between the resonators using the ground vias.

FIG. 13 is a diagram showing a configuration example for adjusting electric field coupling between resonators.

FIG. 14 is an equivalent circuit diagram of a filter device according to Modification 1.

FIG. 15 is a diagram for explaining a configuration of resonators in a filter device according to Modification 2.

FIG. 16 is a diagram for explaining a topology of a filter device according to Example Embodiment 2 of the present invention.

FIGS. 17A and 17B are diagrams for explaining a topology of a filter device according to Example Embodiment 3 of the present invention.

### DETAILED DESCRIPTION OF THE EXAMPLE EMBODIMENTS

Hereinafter, example embodiments of the present disclosure will be described in detail with reference to the drawings. Note that the same or corresponding components in the drawings will be denoted by the same reference numerals, and description thereof will not be repeated.

### Example Embodiment 1

### Basic Configuration of Communication Device

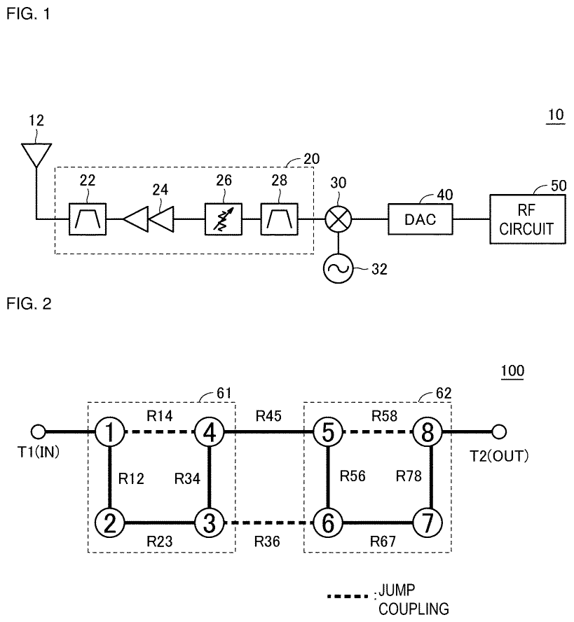

FIG. 1 is a block diagram of a communication device 10 having a high-frequency front-end circuit 20 to which a filter device 100 according to Example Embodiment 1 is applied. The communication device 10 is, for example, a mobile terminal such as a smartphone, or a mobile phone base station.

With reference to FIG. 1, the communication device 10 includes an antenna 12, the high-frequency front-end circuit 20, a mixer 30, a local oscillator 32, a D/A converter (DAC) 40, and an RF circuit 50. The high-frequency front-end circuit 20 includes band pass filters 22 and 28, an amplifier 24, and an attenuator 26. In FIG. 1, the high-frequency front-end circuit 20 includes a transmission circuit that transmits a high frequency signal from the antenna 12. However, the high-frequency front-end circuit 20 may include a reception circuit that receives a high frequency signal through the antenna 12.

The communication device 10 up-converts the transmission signal transmitted from the RF circuit 50 to a high frequency signal and radiates the high frequency signal from the antenna 12. A modulated digital signal, which is the transmission signal outputted from the RF circuit 50, is converted to an analog signal by a D/A converter 40. The mixer 30 mixes the transmission signal, which has been converted from the digital signal to the analog signal by the D/A converter 40, with an oscillation signal from the local oscillator 32 and up-converts the signal thus obtained to a high frequency signal. The band pass filter 28 eliminates unwanted waves generated by the up-conversion and extracts only a transmission signal in a desired frequency band. The attenuator 26 adjusts the strength of the transmission signal. The amplifier 24 amplifies the power of the transmission signal that has passed through the attenuator 26 to a predetermined level. The band pass filter 22 eliminates unwanted waves generated through the amplification process and passes only signal components in a frequency band defined by a communication standard. The transmission signal that has passed through the band pass filter 22 is radiated from the antenna 12.

A filter device according to an example embodiment of the present disclosure can be used as the band pass filters 22 and 28 in the communication device 10 described above.

### Configuration of Filter Device

Next, a configuration of the filter device 100 according to Example Embodiment 1 will be described with reference to FIGS. 2 to 6.

### (1) Topology of Filter Device

FIG. 2 is a diagram for explaining a topology showing a coupling state between resonators in the filter device 100. With reference to FIG. 2, the filter device 100 of Example Embodiment 1 generally has a configuration in which two filters 61 and 62 are cascade-connected between an input terminal T1 and an output terminal T2.

Each of the filters 61 and 62 is a band pass filter including four resonators, for example. In other words, the filter device 100 is an eight-stage filter device including eight resonators, for example. In FIG. 2, nodes indicated by numbers correspond to the respective resonators. The numbers shown on the nodes indicate the order of a main signal transmission path (hereinafter also referred to as a “main path”) from the input terminal T1 to the output terminal T2. In the following description, the numbers of the nodes may be used to express the resonators as the “first-stage resonator” and the “second-stage resonator”.

In the filters 61 and 62, the resonators are electromagnetically coupled to each other along the main path. The resonators are actually coupled by both magnetic coupling and electric field coupling. In this specification, however, the coupling state with a relatively greater strength will be expressed as the coupling state between the resonators.

In the filters 61 and 62, in addition to the main path indicated by the solid line, there is also a sub-path in which two resonators are coupled so as to bypass the series path of the main path. Specifically, in the filter 61, coupling R12 between the first-stage resonator and the second-stage resonator, coupling R23 between the second-stage resonator and the third-stage resonator, and coupling R34 between the third-stage resonator and the fourth-stage resonator define the main path, while coupling R14 between the first-stage resonator and the fourth-stage resonator indicated by the dashed line is the sub-path. Similarly, in the filter 62, coupling R56 between the fifth-stage resonator and the sixth-stage resonator, coupling R67 between the sixth-stage resonator and the seventh-stage resonator, and coupling R78 between the seventh-stage resonator and the eighth-stage resonator define the main path, while coupling R58 between the fifth-stage resonator and the eighth-stage resonator indicated by the dashed line is the sub-path.

Such coupling by the sub-path is generally called “jump coupling”. It is known that an attenuation pole can be added to the filter device by forming “jump coupling”.

The filter device 100 is configured such that the filter 61 and the filter 62 are coupled by two paths. One coupling is coupling R45 between the fourth-stage resonator and the fifth-stage resonator. The other coupling is coupling R36 between the third-stage resonator and the sixth-stage resonator. The coupling R45 corresponds to main path coupling, and the coupling R36 corresponds to sub-path coupling, that is, “jump coupling”.

In the filter device 100 of Example Embodiment 1, the two filters are coupled by two paths, the main path and the sub-path, to form jump coupling. This makes it possible to add an attenuation pole to a non-pass band on the higher frequency side and a non-pass band on the lower frequency side of a pass band, compared to the case of coupling by the main path only. Furthermore, in the filter device 100, one of the main path and the sub-path is magnetically coupled, and the other is electric field coupled. By adopting such a coupling state, a phase difference can be generated between the paths. Therefore, the attenuation characteristics in the non-pass band can be improved by adopting a topology such as that of the filter device 100.

### (2) Equivalent Circuit

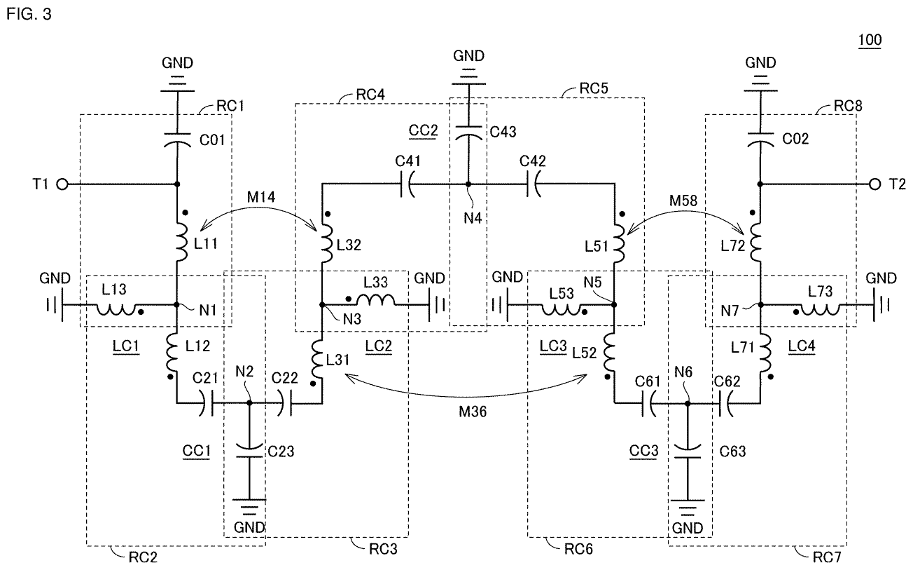

FIG. 3 is an example of an equivalent circuit diagram of the filter device 100. In the equivalent circuit of FIG. 3, the filter device 100 includes four inductor circuits LC1 to LC4, three capacitor circuits CC1 to CC3, and capacitors C01 and C02.

Each of the inductor circuits LC1 to LC4 is a T-type circuit including three inductors, for example. Specifically, the inductor circuit LC1 includes inductors L11 to L13, with the inductor L13 connected between a connection node N1 between the series-connected inductors L11 and L12 and a ground potential GND.

Similarly, the inductor circuit LC2 includes inductors L31 to L33, with the inductor L33 connected between a connection node N3 between the series-connected inductors L31 and L32 and the ground potential GND. The inductor circuit LC3 includes inductors L51 to L53, with the inductor L53 connected between a connection node N5 between the series-connected inductors L51 and L52 and the ground potential GND. The inductor circuit LC4 includes inductors L71 to L73, with the inductor L73 connected between a connection node N7 between the series-connected inductors L71 and L72 and the ground potential GND.

Each of the capacitor circuits CC1 to CC3 is a T-type circuit including three capacitors, for example. Specifically, the capacitor circuit CC1 includes capacitors C21 to C23, with the capacitor C23 connected between a connection node N2 between the series-connected capacitors C21 and C22 and the ground potential GND.

Similarly, the capacitor circuit CC2 includes capacitors C41 to C43, with the capacitor C43 connected between a connection node N4 between the series-connected capacitors C41 and C42 and the ground potential GND. The capacitor circuit CC3 includes capacitors C61 to C63, with the capacitor C63 connected between a connection node N6 between the series-connected capacitors C61 and C62 and the ground potential GND.

The filter device 100 is configured such that the inductor circuits and the capacitor circuits are alternately connected between the input terminal T1 and the output terminal T2. Specifically, the inductor L11 in the inductor circuit LC1 is connected to the input terminal T1. The inductor L12 of the inductor circuit LC1 is connected to the capacitor C21 of the capacitor circuit CC1. The capacitor C22 of the capacitor circuit CC1 is connected to the inductor L31 of the inductor circuit LC2. The inductor L32 of the inductor circuit LC2 is connected to the capacitor C41 of the capacitor circuit CC2.

The capacitor C42 of the capacitor circuit CC2 is connected to the inductor L51 of the inductor circuit LC3. The inductor L52 of the inductor circuit LC3 is connected to the capacitor C61 of the capacitor circuit CC3. The capacitor C62 of the capacitor circuit CC3 is connected to the inductor L71 of the inductor circuit LC4. The inductor L72 of the inductor circuit LC4 is connected to the output terminal T2.

The inductor L11 is also connected to a ground terminal GND through the capacitor C01, and the inductor L72 of the inductor circuit LC4 is connected to the ground potential GND through the capacitor C02. The inductor L11 may be connected to the input terminal T1 through a capacitor that is not shown. The inductor L72 may be connected to the output terminal T2 through a capacitor that is not shown.

A first-stage resonator RC1 includes the capacitor C01 and the inductors L11 and L13 of the inductor circuit LC1 in the equivalent circuit of FIG. 3. A second-stage resonator RC2 includes the inductors L12 and L13 of the inductor circuit LC1 and the capacitors C21 and C23 of the capacitor circuit CC1. A third-stage resonator RC3 includes the capacitors C22 and C23 of the capacitor circuit CC1 and the inductors L31 and L33 of the inductor circuit LC2.

A fourth-stage resonator RC4 includes the inductors L32 and L33 of the inductor circuit LC2 and the capacitors C41 and C43 of the capacitor circuit CC2. A fifth-stage resonator RC5 includes the capacitors C42 and C43 of the capacitor circuit CC2 and the inductors L51 and L53 of the inductor circuit LC3.

A sixth-stage resonator RC6 includes the inductors L52 and L53 of the inductor circuit LC3 and the capacitors C61 and C63 of the capacitor circuit CC3. A seventh-stage resonator RC7 includes the capacitors C62 and C63 of the capacitor circuit CC3 and the inductors L71 and L73 of the inductor circuit LC4. An eighth-stage resonator RC8 includes the inductors L72 and L73 of the inductor circuit LC4 and the capacitor C02.

The inductor L11 in the inductor circuit LC1 is magnetically coupled (M14) to the inductor L32 in the inductor circuit LC2, and the inductor L31 in the inductor circuit LC2 is magnetically coupled (M36) to the inductor L52 in the inductor circuit LC3. The inductor L51 in the inductor circuit LC3 is magnetically coupled (M58) to the inductor L72 in the inductor circuit LC4. These magnetic couplings form jump coupling between the resonator RC1 and the resonator RC4, jump coupling between the resonator RC3 and the resonator RC6, and jump coupling between the resonator RC5 and the resonator RC8.

### (3) Detailed Configuration

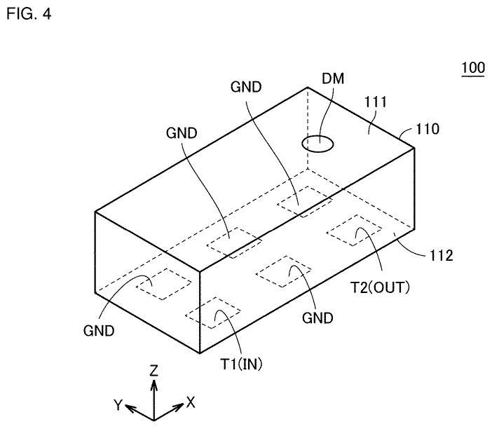

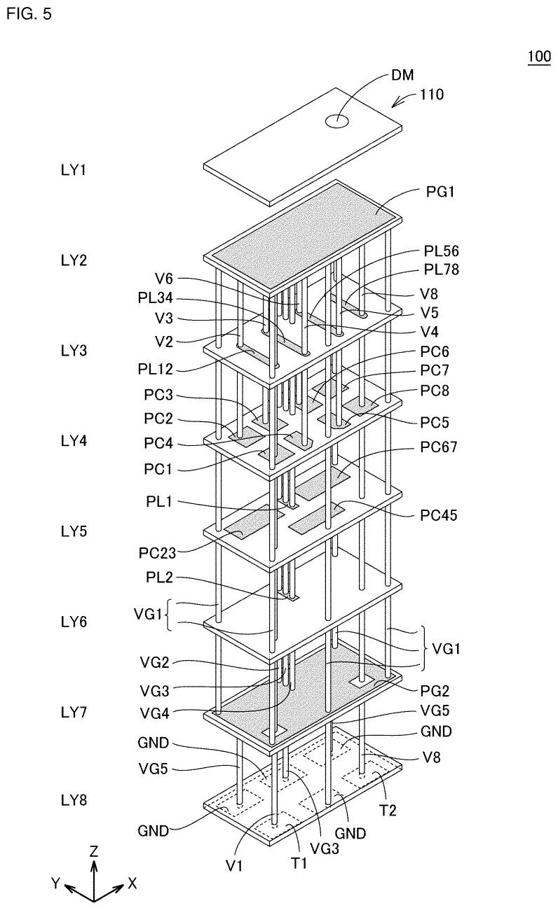

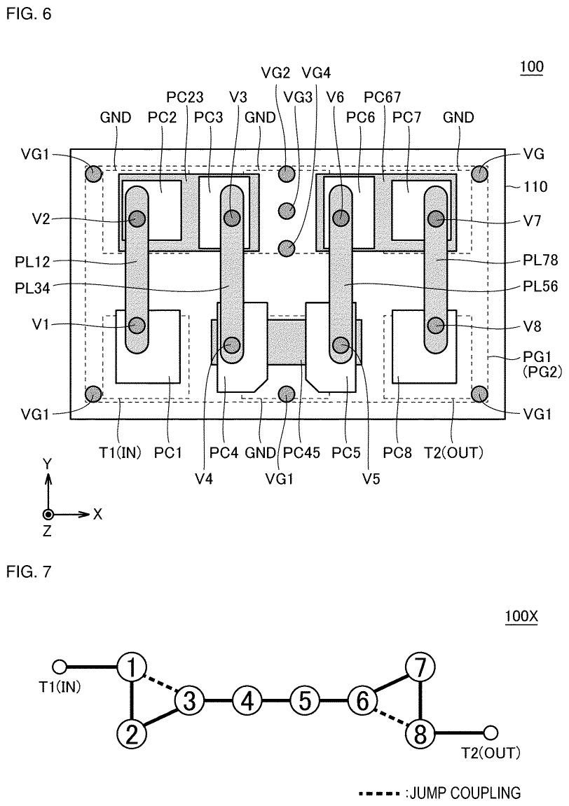

Next, a detailed configuration of the filter device 100 will be described with reference to FIGS. 4 to 6. FIG. 4 is an external perspective view of the filter device 100. FIG. 5 is an exploded perspective view showing an example of a multilayer structure of the filter device 100. FIG. 6 is a top view of the filter device 100.

With reference to FIGS. 4 to 6, the filter device 100 includes a rectangular parallelepiped or substantially rectangular parallelepiped multilayer body 110 (dielectric substrate) in which a plurality of dielectric layers LY1 to LY8 are laminated in a lamination direction. The dielectric layers LY1 to LY8 are formed of ceramics such as low temperature co-fired ceramics (LTCC) or resin. Inside the multilayer body 110, the inductors and capacitors of the LC parallel resonators are formed by a plurality of electrodes provided on each dielectric layer and a plurality of vias provided between the dielectric layers. In this specification, the term “via” refers to a conductor provided in the dielectric layer to connect electrodes provided on different dielectric layers. The via is formed of, for example, conductive paste, plating, and/or a metal pin.

In the following description, the lamination direction of the dielectric layers LY1 to LY8 in the multilayer body 110 will be referred to as a “Z-axis direction”, the direction perpendicular to the Z-axis direction and along the long side of the multilayer body 110 will be referred to as an “X-axis direction”, and the direction perpendicular to the Z-axis direction and along the short side of the multilayer body 110 will be referred to as a “Y-axis direction”. Hereinafter, the positive direction of the Z-axis in each drawing may be referred to as the upper side and the negative direction thereof as the lower side.

A direction mark DM for identifying the orientation of the filter device 100 is provided on an upper surface 111 (dielectric layer LY1) of the multilayer body 110. External terminals (an input terminal T1, an output terminal T2, and a plurality of ground terminals GND) are disposed on a lower surface 112 (dielectric layer LY8) of the multilayer body 110 to connect the filter device 100 to an external device. The input terminal T1, the output terminal T2, and the ground terminals GND are each a flat electrode, and are land grid array (LGA) terminals arranged at regular intervals on the lower surface 112 of the multilayer body 110.

As described with reference to FIGS. 2 and 3, the filter device 100 includes the eight resonators RC1 to RC8, which are LC parallel resonators. More specifically, the resonator RC1 includes a via V1 and a capacitor electrode PC1. The resonator RC2 includes a via V2 and a capacitor electrode PC2. The resonator RC3 includes a via V3 and a capacitor electrode PC3. The resonator RC4 includes a via V4 and a capacitor electrode PC4. The resonator RC5 includes a via V5 and a capacitor electrode PC5. The resonator RC6 includes a via V6 and a capacitor electrode PC6. The resonator RC7 includes a via V7 and a capacitor electrode PC7. The resonator RC8 includes a via V8 and a capacitor electrode PC8.

The dielectric layers LY2 and LY7 of the multilayer body 110 includes ground electrodes PG1 and PG2, respectively, disposed over almost the entire surface thereof. The ground electrodes PG1 and PG2 are connected to each other by a plurality of ground vias VG1. The ground electrode PG2 is connected to the ground terminal GND of the dielectric layer LY8 by a plurality of ground vias VG5.

The via V1 that defines the resonator RC1 is connected to a ground electrode PG1 disposed in the dielectric layer LY2 from the input terminal T1 through the ground electrode PG2 disposed in the dielectric layer LY7. The via V1 is also connected to the capacitor electrode PC1 disposed in the dielectric layer LY4. The via V1 corresponds to the inductors L11 and L13 in FIG. 3.

The capacitor electrode PC1 is a plate electrode having a substantially rectangular shape. When viewed in plan view from the normal direction (that is, Z-axis direction) of the upper surface 111 of the multilayer body 110, the capacitor electrode PC1 at least partially overlaps with the ground electrode PG2. The capacitor electrode PC1 and the ground electrode PG2 define the capacitor C01 in FIG. 3. The via V1 and the capacitor electrode PC1 thus define a one-side open LC resonator.

The via V2 that defines the resonator RC2 has one end connected to the capacitor electrode PC2 disposed in the dielectric layer LY4 and the other end connected to the ground electrode PG1. The via V2 corresponds to the inductors L12 and L13 in FIG. 3.

The capacitor electrode PC2 is spaced apart from the capacitor electrode PC1 in the positive direction of the Y-axis in the dielectric layer LY4. In plan view from the Z-axis direction, the capacitor electrode PC2 at least partially overlaps with the capacitor electrode PC23 disposed in the dielectric layer LY5.

The capacitor electrode PC23 is a plate electrode having a substantially rectangular shape with its long sides in the X-axis direction. In plan view from the Z-axis direction, the capacitor electrode PC23 overlaps with the ground electrode PG2 in the dielectric layer LY7. The capacitor electrode PC2 and the capacitor electrode PC23 define the capacitor C21 in FIG. 3. The capacitor electrode PC23 and the ground electrode PG2 define the capacitor C23 in FIG. 3. The via V2 and the capacitor electrodes PC2 and PC23 thus define a one-side open LC resonator.

The via V1 included in the resonator RC1 and the via V2 included in the resonator RC2 are connected to each other by a plate electrode PL12 disposed in the dielectric layer LY3. The plate electrode PL12 is a strip-shaped electrode extending in the Y-axis direction, with one end connected to the via V1 and the other end connected to the via V2. The plate electrode PL12 causes the main coupling between the resonators RC1 and RC2 to be magnetic coupling.

The via V3 that defines the resonator RC3 has one end connected to the capacitor electrode PC3 disposed in the dielectric layer LY4 and the other end connected to the ground electrode PG1. The via V3 corresponds to the inductors L31 and L33 in FIG. 3.

The capacitor electrode PC3 is spaced apart from the capacitor electrode PC2 in the positive direction of the X-axis in the dielectric layer LY4. In plan view from the Z-axis direction, the capacitor electrode PC3 also at least partially overlaps with the capacitor electrode PC23 disposed in the dielectric layer LY5. The capacitor electrode PC3 and the capacitor electrode PC23 define the capacitor C22 in FIG. 3. The via V3 and the capacitor electrodes PC3 and PC23 thus define a one-side open LC resonator.

Here, the capacitor electrode PC2 included in the resonator RC2 and the capacitor electrode PC3 included in the resonator RC3 share the capacitor electrode PC23. This causes the main coupling between the resonators RC2 and RC3 to be electric field coupling.

The via V4 that defines the resonator RC4 has one end connected to the capacitor electrode PC4 disposed in the dielectric layer LY4 and the other end connected to the ground electrode PG1. The via V4 corresponds to the inductors L32 and L33 in FIG. 3.

The capacitor electrode PC4 is spaced apart from the capacitor electrode PC3 in the negative direction of the Y-axis and spaced apart from the capacitor electrode PC1 in the positive direction of the X-axis in the dielectric layer LY4. In plan view from the Z-axis direction, the capacitor electrode PC4 at least partially overlaps with the capacitor electrode PC45 disposed in the dielectric layer LY5.

The capacitor electrode PC45 is a plate electrode having a substantially rectangular shape with its long sides in the X-axis direction. In plan view from the Z-axis direction, the capacitor electrode PC45 overlaps with the ground electrode PG2 in the dielectric layer LY7. The capacitor electrode PC4 and the capacitor electrode PC45 define the capacitor C41 in FIG. 3. Alternatively, the capacitor electrode PC45 and the ground electrode PG2 define the capacitor C43 in FIG. 3. The via V4 and the capacitor electrodes PC4 and PC45 thus define a one-side open LC resonator.

The via V3 included in the resonator RC3 and the via V4 included in the resonator RC4 are connected to each other by a plate electrode PL34 disposed in the dielectric layer LY3. The plate electrode PL34 is a strip-shaped electrode extending in the Y-axis direction, with one end connected to the via V3 and the other end connected to the via V4. The plate electrode PL34 causes the main coupling between the resonators RC3 and RC4 to be magnetic coupling.

Since the resonator RC4 is disposed adjacent to the resonator RC1 in the X-axis direction, the resonators RC4 and RC1 are substantially coupled. Specifically, the vias V1 and V4 cause magnetic coupling, and the capacitor electrodes PC1 and PC4 cause electric field coupling. The main coupling between the resonators RC1 and RC4 is determined by the coupling strength between the vias and the coupling strength between the capacitor electrodes. This causes jump coupling to be formed between the resonators RC3 and RC4.

The via V5 that defines the resonator RC5 has one end connected to the capacitor electrode PC5 disposed in the dielectric layer LY4 and the other end connected to the ground electrode PG1. The via V5 corresponds to the inductors L51 and L53 in FIG. 3.

The capacitor electrode PC5 is spaced apart from the capacitor electrode PC4 in the positive direction of the X-axis in the dielectric layer LY4. In plan view from the Z-axis direction, the capacitor electrode PC5 at least partially overlaps with the capacitor electrode PC45 disposed in the dielectric layer LY5. The capacitor electrodes PC5 and PC45 define the capacitor C42 in FIG. 3. The via V5 and the capacitor electrodes PC5 and PC45 thus define a one-side open LC resonator.

Here, the capacitor electrode PC4 included in the resonator RC4 and the capacitor electrode PC5 included in the resonator RC5 share the capacitor electrode PC45. This causes the main coupling between the resonators RC4 and RC5 to be electric field coupling.

The via V6 that defines the resonator RC6 has one end connected to the capacitor electrode PC6 disposed in the dielectric layer LY4 and the other end connected to the ground electrode PG1. The via V6 corresponds to the inductors L52 and L53 in FIG. 3.

The capacitor electrode PC6 is spaced apart from the capacitor electrode PC4 in the positive direction of the Y-axis and spaced apart from the capacitor electrode PC3 in the positive direction of the X-axis in the dielectric layer LY4. In plan view from the Z-axis direction, the capacitor electrode PC6 at least partially overlaps with the capacitor electrode PC67 disposed in the dielectric layer LY5.

The capacitor electrode PC67 is a plate electrode having a substantially rectangular shape with its long sides in the X-axis direction. The capacitor electrode PC67 is spaced apart from the capacitor electrode PC23 in the positive direction of the X-axis. In plan view from the Z-axis direction, the capacitor electrode PC67 overlaps with the ground electrode PG2 in the dielectric layer LY7. The capacitor electrodes PC6 and PC67 define the capacitor C61 in FIG. 3. The capacitor electrode PC67 and the ground electrode PG2 define the capacitor C63 in FIG. 3. The via V6 and the capacitor electrodes PC6 and PC67 thus define a one-side open LC resonator.

The via V5 included in the resonator RC5 and the via V6 included in the resonator RC6 are connected to each other by a plate electrode PL56 disposed in the dielectric layer LY3. The plate electrode PL56 is a strip-shaped electrode extending in the Y-axis direction, with one end connected to the via V5 and the other end connected to the via V6. The plate electrode PL56 causes the main coupling between the resonators RC5 and RC6 to be magnetic coupling.

Between the via V3 of the resonator RC3 and the via V6 of the resonator RC6, ground vias VG2, VG3, and VG4 are disposed, each having one end connected to the ground electrode PG1 and the other end connected to the ground electrode PG2. The ground vias VG2, VG3, and VG4 are arranged side by side in the Y-axis direction. The ground vias VG2, VG3, and VG4 are connected to each other by the plate electrode PL1 disposed in the dielectric layer LY5 and the plate electrode PL2 disposed in the dielectric layer LY6.

Since the resonator RC6 is adjacent to the resonator RC3 in the X-axis direction, the resonators RC6 and RC3 are substantially coupled to each other, thus defining jump coupling. The ground vias VG2, VG3, and VG4 are adjustment vias for adjusting the degree of coupling between the resonators RC3 and RC6. Here, in the filter device 100, the ground vias VG2, VG3, and VG4 thus provided make it possible to design the magnetic coupling to be smaller than when the ground vias VG2, VG3, and VG4 are not provided. The degree of magnetic coupling is adjusted by changing the number and intervals of the ground vias. The electric field components of the resonators in the filter device 100, including the resonators RC3 and RC6, are concentrated near the capacitor electrodes. This causes the main coupling between the resonators RC3 and RC6 to be magnetic coupling.

The via V7 that defines the resonator RC7 has one end connected to the capacitor electrode PC7 disposed in the dielectric layer LY4 and the other end connected to the ground electrode PG1. The via V7 corresponds to the inductors L71 and L73 in FIG. 3.

The capacitor electrode PC7 is spaced apart from the capacitor electrode PC6 in the positive direction of the X-axis in the dielectric layer LY4. In plan view from the Z-axis direction, the capacitor electrode PC7 also at least partially overlaps with the capacitor electrode PC67 disposed in the dielectric layer LY5. The capacitor electrodes PC6 and PC67 define the capacitor C62 in FIG. 3. The via V7 and the capacitor electrodes PC7 and PC67 thus define a one-side open LC resonator.

Here, the capacitor electrode PC6 included in the resonator RC6 and the capacitor electrode PC7 included in the resonator RC7 share the capacitor electrode PC67. This causes the main coupling between the resonators RC6 and RC7 to be electric field coupling.

The via V8 that defines the resonator RC8 has one end connected to the ground electrode PG1 and the other end connected to the output terminal T2 disposed in the dielectric layer LY8 through the ground electrode PG2. The via V8 is also connected to the capacitor electrode PC8 disposed in the dielectric layer LY4. The via V8 corresponds to the inductors L72 and L73 in FIG. 3.

The capacitor electrode PC8 is a plate electrode having a substantially rectangular shape. In plan view from the Z-axis direction, the capacitor electrode PC8 at least partially overlaps with the ground electrode PG2. The capacitor electrode PC8 and the ground electrode PG2 define the capacitor C02 in FIG. 3. The via V8 and the capacitor electrode PC8 thus define a one-side open LC resonator.

The via V7 included in the resonator RC7 and the via V8 included in the resonator RC8 are connected to each other by the plate electrode PL78 disposed in the dielectric layer LY3. The plate electrode PL78 is a strip-shaped electrode extending in the Y-axis direction, with one end connected to the via V7 and the other end connected to the via V8. The plate electrode PL78 causes the main coupling between the resonators RC7 and RC8 to be magnetic coupling.

Since the resonator RC8 is adjacent to the resonator RC5 in the X-axis direction, the resonators RC8 and RC5 are substantially coupled to each other. Specifically, the vias V5 and V8 cause magnetic coupling, and the capacitor electrodes PC5 and PC8 cause electric field coupling. The main coupling between the resonators RC5 and RC8 is determined by the coupling strength between the vias and the coupling strength between the capacitor electrodes. This causes jump coupling to be formed between the resonators RC5 and RC8.

In the filter device 100 of Example Embodiment 1, the resonators RC1 to RC4 define a four-stage band pass filter (first filter) having jump coupling between the resonators RC1 and RC4, and the resonators RC5 to RC8 define a four-stage band pass filter (second filter) having jump coupling between the resonators RC5 and RC8. These two band pass filters are coupled by electric field coupling between the resonators RC4 and RC5 and magnetic coupling corresponding to the jump coupling between the resonators RC3 and RC6. With such a configuration in which the two band pass filters are coupled in two coupling states with different polarities and one coupling is jump coupling, attenuation poles can be added to each non-pass band on the higher and lower frequency sides of the pass band, as described with reference to FIG. 2. This can increase the degree of freedom in designing to form the attenuation poles, thus making it possible to improve the attenuation characteristics of the non-pass bands in the eight-stage band pass filter.

As shown in FIG. 6, the elements disposed in the multilayer body 110 are arranged symmetrically with respect to a virtual line along the Y-axis through the center of the multilayer body 110. Such a symmetrical structure causes the filter characteristics to be also symmetrical, thus making it easier to adjust the degree of coupling between the resonators, compared to a filter device with an asymmetric structure. This makes it possible to increase the degree of freedom in designing and makes it easier to realize desired characteristics.

Furthermore, the input terminal T1 and the output terminal T2 are disposed at opposing end portions (that is, the end portion in the positive direction of the X-axis and the end portion in the negative direction thereof) in the long side direction of the multilayer body 110, and the ground terminal GND is disposed between the input terminal T1 and the output terminal T2. This makes it possible to improve the isolation between the input terminal T1 and the output terminal T2.

### (4) Filter Characteristics

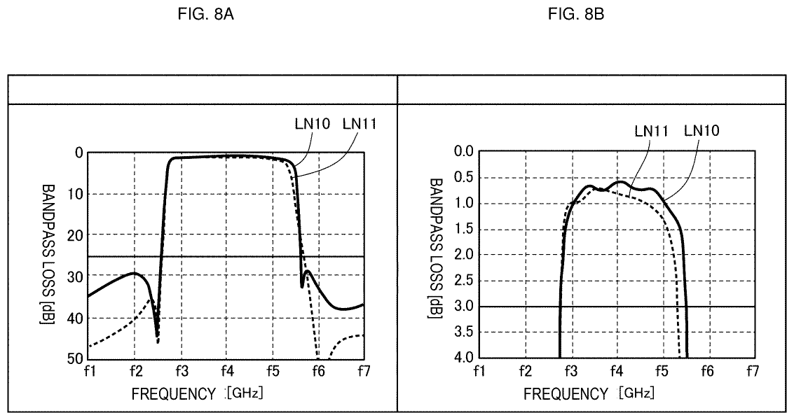

Next, the filter characteristics of the filter device 100 according to Example Embodiment 1 will be described together with a comparative example with reference to FIGS. 7 and 8. FIG. 7 is a diagram for explaining a topology of a filter device 100X according to the comparative example. FIGS. 8A and 8B are diagrams for explaining the filter characteristics of the filter devices according to Example Embodiment 1 and the comparative example.

As shown in FIG. 7, the filter device 100X corresponds to the eight-stage filter device in Japanese Patent No. 7111214 described above. Specifically, in the filter device 100x, jump coupling is formed between a first-stage resonator and a third-stage resonator and between a sixth-stage resonator and an eighth-stage resonator.

In FIGS. 8A and 8B, the horizontal axis represents frequency, and the vertical axis represents bandpass loss of the filter device 100 (solid line LN10) and bandpass loss of the filter device 100X (dashed line LN11). The graph on the right side of FIG. 8B is an enlarged view of the vertical axis of the graph on the left side of FIG. 8A.

As shown in the graph on the right side of FIG. 8B, a fractional bandwidth in a portion where the bandpass loss is 3 dB is larger in the filter device 100 of Example Embodiment 1 than in the filter device 100X of the comparative example, making it possible to obtain wide bandpass characteristics. In the example of FIGS. 8A and 8B, the fractional bandwidth in the portion where the bandpass loss is 3 dB is 54.4% in the filter device 100 and 51.5% in the filter device 100X.

As shown in the graph on the left side of FIG. 8A, on the other hand, the fractional bandwidth in a portion where the bandpass loss is 25 dB is smaller in the filter device 100 of Example Embodiment 1 than in the device 100X of the comparative example. That is, the filter device 100 has steeper attenuation characteristics than the filter device 100X. In the example of FIGS. 8A and 8B, the fractional bandwidth in the portion where the bandpass loss is 25 dB is 59.3% in the filter device 100 and 60.1% in the filter device 100X.

As described above, the filter device 100 of Example Embodiment 1 has wider and steeper attenuation characteristics than the filter device 100X of the comparative example, and thus has the attenuation characteristics improved in a non-pass band.

### (5) Method for Adjusting Coupling Between Resonators

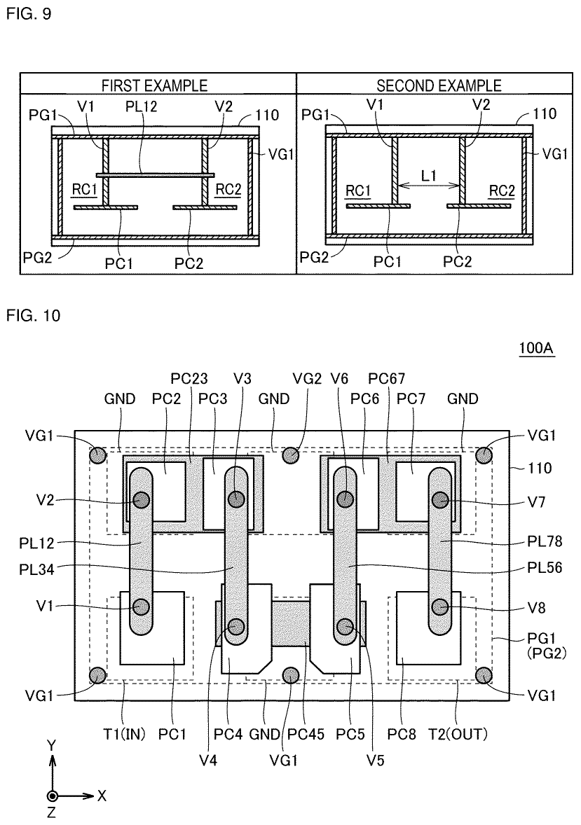

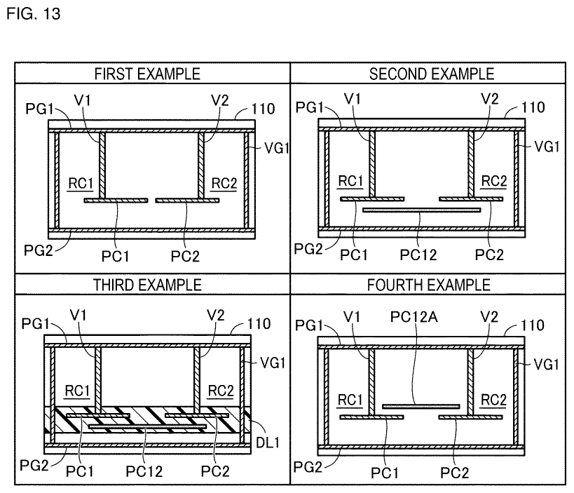

With reference to FIGS. 9 to 13, description will be given of an example of a method for adjusting the degree of coupling between resonators in a filter device. In FIGS. 9 and 13, the coupling between two resonators RC1 and RC2 will be described as an example for ease of explanation.

First, a method for adjusting the magnetic coupling between resonators will be described with reference to FIG. 9. As described with reference to FIG. 5, each resonator is a one-side open LC resonator having one end short-circuited to the ground potential and the other end opened by a capacitor.

In the case of one-side open resonators, the magnetic coupling between the resonators is realized by coupling through the common ground electrode PG1 and by coupling between the vias. Therefore, when the magnetic coupling between two resonators is to be strengthened, it can be adjusted by connecting two vias V1 and V2 with a common plate electrode PL12 as in a first example of FIG. 9, or by shortening a distance L1 between the two vias V1 and V2 as in a second example.

When the magnetic coupling is to be weakened, on the other hand, it can be adjusted by increasing the distance L1 between the vias V1 and V2, or by forming a slit between the vias V1 and V2 in the common ground electrode PG1 to substantially increase the distance between the vias V1 and V2 on the ground electrode PG1.

As shown in FIGS. 10 to 12, the magnetic coupling can also be adjusted by adjusting the number and/or positions of ground vias disposed between two resonators. The ground vias essentially function as a shield against magnetic coupling. Therefore, increasing the number of ground vias between the resonators weakens the magnetic coupling between the resonators. The degree of magnetic coupling can also be adjusted by adjusting the positions of the ground vias from the path that connects the vias of the two resonators in the shortest distance.

In the example of a filter device 100A in FIG. 10, the ground vias VG3 and VG4 between the resonators RC3 and RC6 in the filter device 100 shown in FIG. 6 are omitted, and only the ground via VG2 is provided. In this case, the degree of magnetic coupling between the resonators RC3 and RC6 is stronger than in the case of the filter device 100.

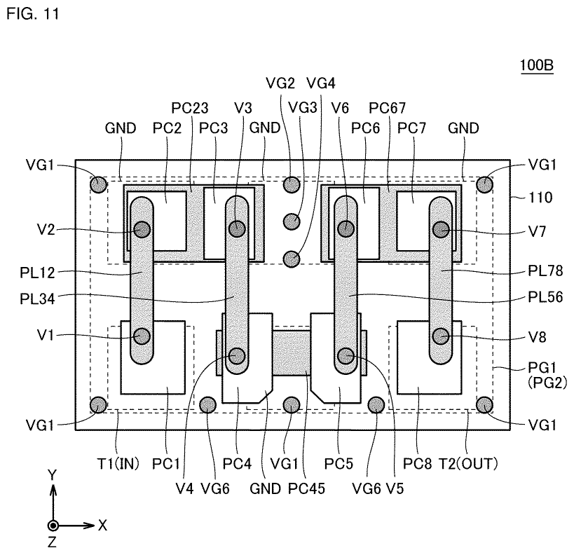

In the example of a filter device 100B in FIG. 11, ground vias VG6 are added between the resonators RC1 and RC4 and between the resonators RC5 and RC8, in addition to the configuration of the filter device 100 shown in FIG. 6. In this case, the magnetic coupling between the resonators RC1 and RC4 and between the resonators RC5 and RC8 is weakened compared to the filter device 100.

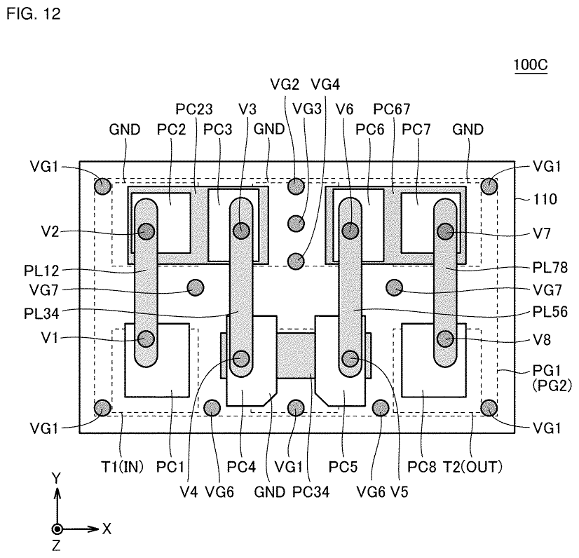

In the example of a filter device 100C in FIG. 12, ground vias VG7 are further added near the center of the first filter and near the center of the second filter, in addition to the configuration in FIG. 11. In this case, the magnetic coupling can be weakened between the resonators RC1 and RC3, between the resonators RC2 and RC4, between the resonators RC5 and RC7, and between the resonators RC6 and RC8. The ground via VG7 eliminates unwanted magnetic coupling between the resonators, thus making it possible to reduce or prevent unintended deterioration in filter characteristics.

Next, a non-limiting example of a method for adjusting electric field coupling between resonators will be described with reference to FIG. 13. In the case of one-side open resonators, electric field coupling between the resonators is realized by coupling between two capacitor electrodes PC1 and PC2. Therefore, when the electric field coupling between two resonators is to be strengthened, it can be adjusted by reducing the distance between the two adjacent capacitor electrodes PC1 and PC2, as in a first example.

Alternatively, as in the configuration of FIG. 5, the electric field coupling can also be adjusted by providing a capacitor electrode PC12, which is coupled to both of the capacitor electrodes PC1 and PC2, between the capacitor electrodes PC1 and PC2 and the ground electrode PG2, as in a second example. In this case, the degree of coupling can be adjusted by adjusting the distance between the capacitor electrodes PC1 and PC2 and the capacitor electrode PC12 and/or the opposing area between the capacitor electrodes PC1 and PC2 and the capacitor electrode PC12.

As in a third example, the degree of electric field coupling can be further strengthened by providing a dielectric layer DL1 with a relatively high dielectric constant between the capacitor electrodes PC1 and PC2 and the capacitor electrode PC12.

Note that the capacitor electrode coupled to both of the two resonators can also be disposed on the upper side of the capacitor electrodes PC1 and PC2, that is, on the ground electrode PG1 side, as in the case of a capacitor electrode PC12A in a fourth example. Such a configuration with the capacitor electrode PC12A can increase the distance from the ground electrode PG2 compared to the case of the capacitor electrode PC12 in the second example. This makes it possible to relatively increase the capacitance between the resonators, thus strengthening the electric field coupling between the resonators.

### (6) Modifications

### Modification 1

In Modification 1, description will be given of a configuration with different capacitor circuits in the equivalent circuit shown in FIG. 3.

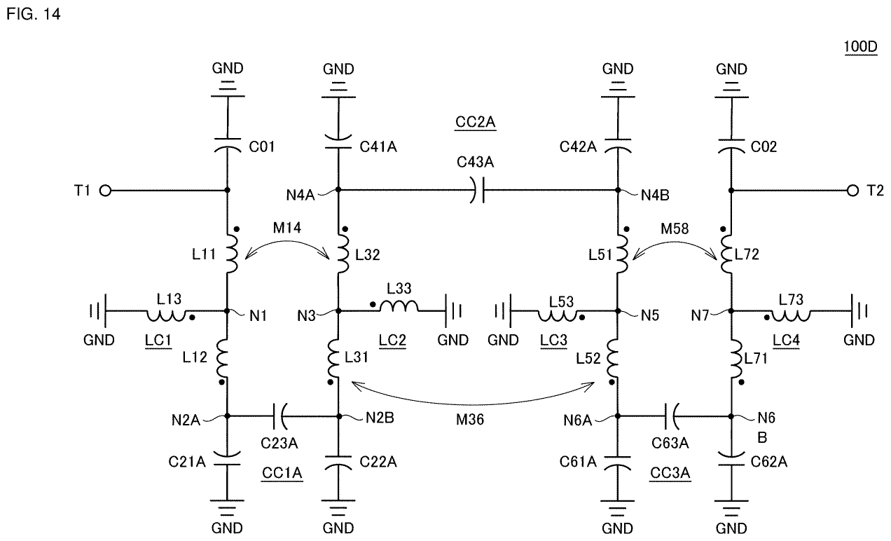

FIG. 14 is an equivalent circuit diagram of a filter device 100D of Modification 1. In the filter device 100D, n-type capacitor circuits CC1A to CC3A are disposed in place of the T-type capacitor circuits CC1 to CC3 of the filter device 100 in FIG. 3.

The capacitor circuits CC1A to CC3A each include three capacitors connected in series between ground potentials GND, and each connection node of the capacitors is connected to an adjacent inductor circuit. Specifically, the capacitor circuit CC1A includes capacitors C21A, C22A, and C23A. The capacitor C23A has one end connected to the ground potential GND through the capacitor C21A and the other end connected to the ground potential GND through the capacitor C22A. A connection node N2A between the capacitor C21A and the capacitor C23A is connected to an inductor L12 of an inductor circuit LC1. A connection node N2B between the capacitor C22A and the capacitor C23A is connected to an inductor L31 of an inductor circuit LC2.

The capacitor circuit CC2A includes capacitors C41A, C42A, and C43A. The capacitor C43A has one end connected to the ground potential GND through the capacitor C41A and the other end connected to the ground potential GND through the capacitor C42A. A connection node N4A between the capacitor C41A and the capacitor C43A is connected to an inductor L32 of an inductor circuit LC3. A connection node N4B between the capacitor C42A and the capacitor C43A is connected to an inductor L51 of an inductor circuit LC3.

The capacitor circuit CC3A includes capacitors C61A, C62A, and C63A. The capacitor C63A has one end connected to the ground potential GND through the capacitor C61A and the other end connected to the ground potential GND through the capacitor C62A. A connection node N6A between the capacitor C61A and the capacitor C63A is connected to an inductor L52 of an inductor circuit LC3. A connection node N6B between the capacitor C62A and the capacitor C63A is connected to an inductor L71 of an inductor circuit LC4.

Such a configuration with the n-type capacitor circuits can also improve the attenuation characteristics in the non-pass band by coupling two four-stage band pass filters through magnetic coupling and electric field coupling, one of which is jump coupling.

### Modification 2

In Modification 2, description will be given of a configuration in which resonators of a different type from that of Example Embodiment 1 are used.

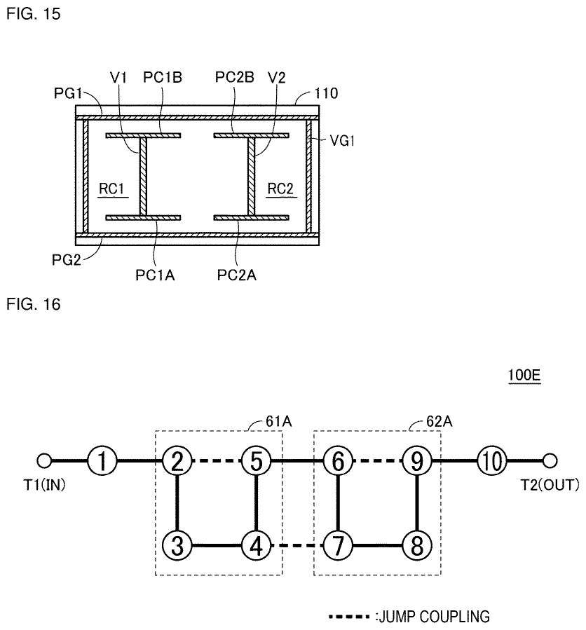

FIG. 15 is a diagram for explaining a configuration of resonators in a filter device of Modification 2. FIG. 15 shows only the configuration of resonators RC1 and RC2 for ease of explanation.

With reference to FIG. 15, in the filter device of Modification 2, each resonator is a both-end open resonator having a plate-shaped capacitor electrode connected to each end of a via. More specifically, the resonator RC1 includes a via V1 and capacitor electrodes PC1A and PC1B. The capacitor electrode PC1A is connected to an end portion of the via V1 on the ground electrode PG1 side and faces the ground electrode PG1. The capacitor electrode PC1B is connected to an end portion of the via V1 on the ground electrode PG2 side and faces the ground electrode PG2. The resonator RC1 functions as a resonator due to the inductance component of the via V1 and the capacitance components of the capacitors formed by the capacitor electrode PCIA and the ground electrode PG1 and by the capacitor electrode PC1B and the ground electrode PG2.

Similarly, in the resonator RC2, a capacitor electrode PC2A is connected to an end portion of a via V2 on the ground electrode PG1 side, and a capacitor electrode PC2B is connected to an end portion of the via V2 on the ground electrode PG2 side. Other resonators RC3 to RC8 also have the same configuration. Such a configuration with the both-end open resonators used as the respective resonators can also improve the attenuation characteristics in a non-pass band by coupling two four-stage band pass filters through magnetic coupling and electric field coupling, one of which is jump coupling.

When the magnetic coupling between the resonators is to be strengthened in the case of adopting the both-end open resonators, connecting adjacent resonators with a plate electrode as in Example Embodiment 1 may cause the two resonators to appear as one resonator, and the resonators may resonate in different modes. For this reason, it is preferable to adjust the magnetic coupling between the resonators by adjusting the distance between the vias of the resonators.

### Example Embodiment 2

In Example Embodiment 2, description will be given of a configuration in which the features of the present disclosure are applied to a ten-stage filter device.

FIG. 16 is a diagram for explaining a topology of a filter device 100E according to Example Embodiment 2. The filter device 100E is generally configured such that one resonator is added between the first-stage resonator RC1 and the input terminal T1 and between the last-stage resonator RC8 and the output terminal T2 in the filter device 100 of Example embodiment 1. Specifically, a filter 61A including second-stage to fifth-stage resonators corresponds to the filter 61 including the resonators RC1 to RC4 in Example Embodiment 1, and a filter 62A including sixth-stage to ninth-stage resonators corresponds to the filter 62 including the resonators RC5 to RC8 in Example Embodiment 1.

The filter device 100E can also improve the attenuation characteristics in a non-pass band, as with the filter device 100 of Example Embodiment 1, by coupling the filter 61A and the filter 62A through the fifth-stage and sixth-stage resonators and forming jump coupling between the fourth-stage and seventh-stage resonators, with one coupling being magnetic coupling and the other being electric field coupling.

It is also possible to configure the two additional resonators to be disposed only on the input terminal T1 side or the output t terminal T2 side. However, from the viewpoint of structural symmetry, it is preferable to dispose the resonators on the input terminal T1 side and the output terminal T2 side, as shown in FIG. 16.

### Example Embodiment 3

In Example Embodiment 3, description will be given of a configuration in which the features of the present disclosure are applied to a twelve-stage filter device.

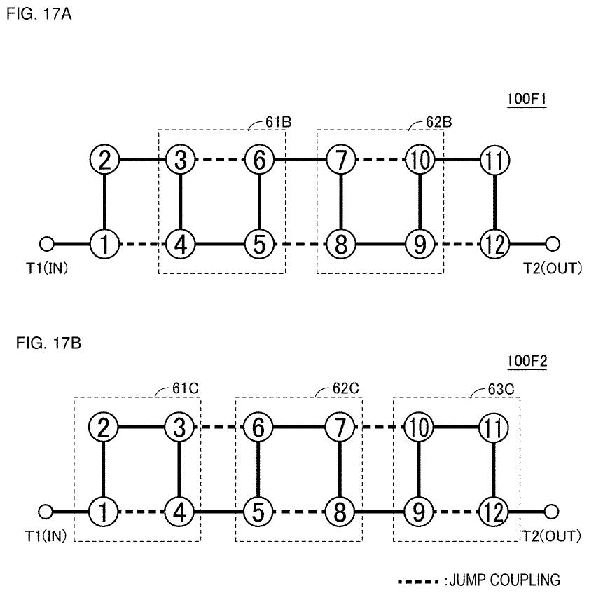

FIGS. 17A and 17B are diagrams for explaining a topology of the filter device according to Example Embodiment 3. A filter device 100F1 shown in the upper portion of FIG. 17A and a filter device 100F2 shown in the lower portion of FIG. 17B have basically the same configuration, but can be considered as follows in comparison with the configuration of Example Embodiment 1.

The filter device 100F1 in the upper portion of FIG. 17A can be considered as a configuration in which two resonators are added between the first-stage resonator RC1 and the input terminal T1 and between the last-stage resonator RC8 and the output terminal T2, in the filter device 100 of Example Embodiment 1. In this case, a filter 61B including third-stage to sixth-stage resonators corresponds to the filter 61 of Example Embodiment 1, and a filter 62B including seventh-stage to tenth-stage resonators corresponds to the filter 62 of Example Embodiment 1.

Therefore, in the filter device 100F1, as in the case of Example Embodiment 2, two four-stage filters are coupled through two paths, one of which is jump coupling. Therefore, the filter device 100F1 can also improve the attenuation characteristics in a non-pass band.

In the case of the filter device 100F2 in the lower portion of FIG. 17B, four-stage filters 61C, 62C, and 63C can be considered to be cascade-connected between the input terminal T1 and the output terminal T2. In this case, the pair of filters 61C and 62C and/or the pair of filters 62C and 63C correspond to the filters 61 and 62 in Example Embodiment 1.

Therefore, in the pair of filters 61C and 62C and the pair of filters 62C and 63C, two four-stage filters are coupled through two paths, one of which is jump coupling. Therefore, the filter device 100F2 can also improve the attenuation characteristics in a non-pass band.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A filter device comprising:
a dielectric substrate including a first main surface and a second main surface;
an input terminal and an output terminal on the second main surface;
a first filter including a first resonator, a second resonator, a third resonator, and a fourth resonator in the dielectric substrate; and
a second filter including a fifth resonator, a sixth resonator, a seventh resonator, and an eighth resonator in the dielectric substrate; wherein
in the first filter, a signal transmitted from the input terminal is transmitted to the second filter through the first resonator, the second resonator, the third resonator, and the fourth resonator in this order;
in the second filter, the signal transmitted from the first filter is transmitted to the output terminal through the fifth resonator, the sixth resonator, the seventh resonator, and the eighth resonator in this order;
jump coupling is present between the third resonator and the sixth resonator; and
one main coupling of coupling between the fourth resonator and the fifth resonator and coupling between the third resonator and the sixth resonator is magnetic coupling, and an other main coupling is electric field coupling.

2. The filter device according to claim 1, wherein jump coupling is present between the first resonator and the fourth resonator in the first filter and between the fifth resonator and the eighth resonator in the second filter.

3. The filter device according to claim 2, wherein main coupling of jump coupling between the first resonator and the fourth resonator and jump coupling between the fifth resonator and the eighth resonator is magnetic coupling.

4. The filter device according to claim 2, wherein main coupling of jump coupling between the first resonator and the fourth resonator and jump coupling between the fifth resonator and the eighth resonator is electric field coupling.

5. The filter device according to claim 1, further comprising:
a first ground electrode facing the first main surface; and
a second ground electrode disposed facing the second main surface between the first ground electrode and the second main surface; wherein
each of the resonators is between the first ground electrode and the second ground electrode.

6. The filter device according to claim 5, wherein
each of the resonators includes:
a via including a first end connected to the first ground electrode; and
a plate electrode connected to a second end of the via and facing the second ground electrode.

7. The filter device according to claim 6, further comprising:
an inductor electrode connecting vias of two resonators with a main coupling that is magnetic coupling in each of the first filter and the second filter.

8. The filter device according to claim 6, wherein
in each of the first filter and the second filter, a distance between vias of two resonators with a main coupling that is magnetic coupling is shorter than a distance between vias of two resonators with a main coupling that is electric field coupling.

9. The filter device according to claim 6, further comprising:
a capacitor electrode facing plate electrodes of two resonators with a main coupling that is electric field coupling in each of the first filter and the second filter.

10. The filter device according to claim 9, wherein
the dielectric substrate includes a plurality of dielectric layers laminated on each other; and
a dielectric constant of one of the dielectric layers between the capacitor electrode and the plate electrode in the dielectric substrate is greater than a dielectric constant of others of the dielectric layers.

11. The filter device according to claim 6, wherein
in each of the first filter and the second filter, a distance between plate electrodes of two resonators with a main coupling that is electric field coupling is shorter than a distance between plate electrodes of two resonators with a main coupling that is magnetic coupling.

12. The filter device according to claim 6, further comprising:
a first inductor electrode connecting vias of the first resonator and the second resonator;
a second inductor electrode connecting vias of the third resonator and the fourth resonator;
a third inductor electrode connecting vias of the fifth resonator and the sixth resonator;
a fourth inductor electrode connecting vias of the seventh resonator and the eighth resonator;
a first capacitor electrode facing a plate electrode of the second resonator and a plate electrode of the third resonator;
a second capacitor electrode facing a plate electrode of the fourth resonator and a plate electrode of the fifth resonator; and
a third capacitor electrode facing a plate electrode of the sixth resonator and a plate electrode of the seventh resonator.

13. The filter device according to claim 12, wherein
the first capacitor electrode, the second capacitor electrode, and the third capacitor electrode are each between a plate electrode of a corresponding resonator and the second ground electrode.

14. The filter device according to claim 12, wherein
the first capacitor electrode, the second capacitor electrode, and the third capacitor electrode are each between a plate electrode of a corresponding resonator and the first ground electrode.

15. The filter device according to claim 5, wherein each of the resonators includes:
a first plate electrode facing the first ground electrode;
a second plate electrode facing the second ground electrode; and
a via including a first end connected to the first plate electrode and a second end connected to the second plate electrode.

16. A filter device comprising:
an input terminal and an output terminal;
a first inductor circuit, a second inductor circuit, a third inductor circuit, and a fourth inductor circuit;
a first capacitor circuit, a second capacitor circuit, and a third capacitor circuit;
a first capacitor connected between the input terminal and a ground potential; and
a second capacitor connected between the output terminal and the ground potential; wherein
the first inductor circuit is connected between the input terminal and the first capacitor circuit;
the second inductor circuit is connected between the first capacitor circuit and the second capacitor circuit;
the second inductor circuit is connected between the second capacitor circuit and the third capacitor circuit;
the fourth inductor circuit is connected between the third capacitor circuit and the output terminal; and
the first inductor circuit and the second inductor circuit are magnetically coupled, the second inductor circuit and the third inductor circuit are magnetically coupled, and the third inductor circuit and the fourth inductor circuit are magnetically coupled.

17. The filter device according to claim 16, wherein
each of the inductor circuits includes:
a first terminal and a second terminal;
a first inductor and a second inductor connected in series between the first terminal and the second terminal; and
a third inductor connected between the ground potential and a connection node between the first inductor and the second inductor.

18. The filter device according to claim 16, wherein
each of the capacitors circuit includes:
a third terminal and a fourth terminal;
a third capacitor and a fourth capacitor connected in series between the third terminal and the fourth terminal; and
a fifth capacitor connected between the ground potential and a connection node between the third capacitor and the fourth capacitor.

19. The filter device according to claim 16, wherein
each of the capacitor circuits includes:
a fifth terminal and a sixth terminal;
a sixth capacitor connected between the fifth terminal and the ground potential;
a seventh capacitor connected between the sixth terminal and the ground potential; and
an eighth capacitor connected between the fifth terminal and the sixth terminal.
